(19) United States
(12) Patent Application Publication
(10) Pub. No.: US 2015/0162443 A1
(43) Pub. Date: Jun. 11, 2015

(54) SEMICONDUCTOR POWER DEVICES AND METHODS OF MANUFACTURING THE SAME

(71) Applicant: Samsung Electronics Co., Ltd., Suwon-si (KR)

(72) Inventors: Jae-Hoon Lee, Suwon-si (KR); Tae-Geun Kim, Bucheon-si (KR); Chan-Ho Park, Seongnam-si (KR); Hyun-Jung Her, Hwaseong-si (KR)

(21) Appl. No.: 14/452,730

(22) Filed: Aug. 6, 2014

(30) Foreign Application Priority Data
Dec. 10, 2013 (KR) 10-2013-0152984

(51) Int. Cl. H01L 29/78; H01L 27/088

(52) U.S. Cl. CPC H01L 29/7827; H01L 27/088

(57) ABSTRACT

In a semiconductor power device and method of the same, the semiconductor device includes a substrate, a gate electrode structure, first impurity regions, an insulating interlayer, first contact plugs and a first metal pattern. The substrate includes an active region and a termination region. The gate electrode structure includes a first gate electrode and a second gate electrode buried in the substrate, and upper surfaces of the gate electrode structure are lower than an upper surface of the substrate between the first and second gate electrodes. The first impurity regions are formed in the substrate between the first and second electrodes. The insulating interlayer having a flat top surface is formed on the substrate and the gate electrode structure. The first contact plugs are formed through the insulating interlayer, and the first contact plugs contact the first impurity regions. The first metal pattern having a flat top surface is formed on the first contact plugs and the insulating interlayer. Defect of the semiconductor power device may be decreased, and the semiconductor power device may have good electric characteristics.

### CROSS-REFERENCE TO RELATED APPLICATION

This U.S. non-provisional patent application claims priority under 35 USC §119 to Korean Patent Application No. 10-2013-0152984, filed on Dec. 10, 2013 in the Korean Intellectual Property Office (KIPO), the contents of which are herein incorporated by reference in their entirety.

### BACKGROUND

1. Field

Example embodiments relate to semiconductor power devices and methods of manufacturing the same. More particularly, example embodiments relate to insulated gate bipolar transistors (IGBTs) and methods of manufacturing the same.

2. Description of the Related Art

A semiconductor power device needs to have a high operating voltage and a high breakdown voltage. Also, the semiconductor power device needs to have a high current density by integrating as many cells as possible in a unit area. A method of manufacturing the semiconductor power device having no defects is needed.

### SUMMARY

An aspect of the present inventive concepts provides a semiconductor power device having reduced defects. Another aspect of the present inventive concepts provides a method of manufacturing a semiconductor power device having reduced defects.

In one example embodiment, the semiconductor power device includes a substrate including an active region and a termination region, a first gate electrode and a second gate electrode buried in the substrate, upper surfaces of the first and second gate electrodes being lower than an upper surface of the substrate therebetween, a first impurity region in the substrate between the first and second electrodes, an insulating interlayer having a flat top surface on the substrate, the insulating interlayer covering the upper surfaces of the first and second gate electrodes, a first contact plug passing through the insulating interlayer to contact with the first impurity region, and a first metal layer pattern having a flat top surface on the first contact plug and the insulating interlayer.

In some embodiments, the semiconductor power device may further include a third gate electrode buried in the substrate, the third gate electrode being spaced apart from the second gate electrode, and a floating well region between the second gate electrode and the third gate electrode.

In some embodiments, the bottommost of the floating well region may have a level lower than the bottommost of the second and third gate electrodes.

In some embodiments, the substrate may be doped with an n-type impurity.

In some embodiments, the floating well region may be doped with a p-type impurity.

In some embodiments, the bottommost of the first impurity region may have a level higher than the bottommost of the first and second gate electrode.

In some embodiments, the semiconductor power device may further include a gate insulating layer between the first, second and third gate electrodes and the substrate.

In some embodiments, the first and second gate electrodes may extend from the active region to the termination region, the first and second gate electrodes having a connecting portion for connecting the first and second gate electrodes to each other in the termination region.

In some embodiments, the connecting portion may have a rounded shape.

In some embodiments, the semiconductor power device may further include a second contact plug passing through the insulating interlayer to contact with the connecting portion, and a second metal layer pattern on the second contact plug and the insulating interlayer, the second metal layer pattern having a flat top surface.

In some embodiments, the second metal layer pattern may be electrically connected to the first and second gate electrodes in the active region.

In some embodiments, the second metal layer pattern may surround the active region.

In some embodiments, the first and second contact plugs may include a metal.

In some embodiments, the semiconductor power device may further include a second impurity region for preventing from a concentration of an electric field in the termination region of the substrate. The second impurity region may be spaced apart from the first and second gate electrodes and surrounding the active region.

In some embodiments, the semiconductor power device may further include a field stop region, a collector region and a third metal layer pattern at a lower portion of the substrate. The field stop region may be between the floating well and the collector region.

In some embodiments, the collector region may be between the field stop region and the third metal layer pattern.

In accordance with another aspect of the present inventive concepts, a semiconductor power device may include a first trench and a second trench in a substrate, a first gate electrode in the first trench and a second gate electrode in the second trench, upper surfaces of the first and second gate electrodes being lower than an upper surface of the substrate therebetween, a first impurity region in the substrate between the first and second electrodes, an insulating interlayer having a flat top surface on the substrate, the insulating interlayer covering the upper surfaces of the first and second gate electrodes, a first contact plug passing through the insulating interlayer to contact with the first impurity region, a first metal layer pattern having a flat top surface on the first contact plug and the insulating interlayer, a collector region disposed at a lower portion of the substrate, and a second metal layer pattern under the collector region.

In some embodiments, the semiconductor power device may further include a third trench in the substrate, the third trench being spaced apart from the second trench, a third gate electrode in the third trench, and a floating well region between the second trench and the third trench.

In some embodiments, the bottommost of the floating well region has a level lower than the bottommost of the second and third trenches.

In accordance with still another aspect of the present inventive concepts, a substrate including an active region and a termination region, a first trench and a second trench in the substrate, a first gate electrode in the first trench and a second gate electrode in the second trench, upper surfaces of the first and second gate electrodes being lower than an upper surface of the substrate therebetween, a first impurity region in the substrate between the first and second electrodes, an insulating interlayer having a flat top surface on the substrate, the insulating interlayer covering the upper surfaces of the first and second gate electrodes, a first contact plug passing through the insulating interlayer to contact with the first impurity region, a first metal layer pattern having a flat top surface on the first contact plug and the insulating interlayer, a collector region disposed at a lower portion of the substrate, and a second metal layer pattern under the collector region. The first and second gate electrodes may extend from the active region to the termination region. The first and second gate electrodes may have a connecting portion for connecting the first and second gate electrodes to each other in the termination region.

In accordance with still another aspect of the present inventive concepts, a method of manufacturing a semiconductor device may be provided. In the method, a trench is formed on a substrate including an active region and a termination region. A gate electrode structure is formed in the trench. The gate electrode structure includes a first gate electrode and a second gate electrode, and has an upper surface lower than an upper surface of the substrate between the first and second gate electrodes. Impurity regions are formed at portions of the substrate between the first and second gate electrodes. An insulating interlayer is formed on the gate electrode structure and the substrate. First contact plugs are formed through the insulating interlayer. The first contact plugs contact the impurity regions. A first metal pattern having a flat top surface is formed on the first contact plugs and the insulating interlayer.

In some embodiments, when the trench is formed, a plurality of trenches may be formed. When the gate electrode structure is formed, a gate electrode layer may be formed to fill the trenches on the substrate. An upper portion of the gate electrode layer may be planarized to form a preliminary first gate electrode and a preliminary second gate electrode in the trenches. Upper portions of the preliminary first and second electrodes may be etched to form the first and second electrodes.

In some embodiments, when the first contact plugs are formed, the insulating interlayer may be partially etched to form first contact holes exposing the impurity regions. An electrode layer may be formed to fill the first contact holes. An upper portion of the electrode layer may be planarized to form the first contact plugs in the first contact holes, respectively.

In some embodiments, the gate electrode may extend from the active region to the termination region on the substrate. When the gate electrode structure is formed, connecting portion may be further formed for connecting the first and second gate electrodes to each other in the termination region. The gate electrode structure may be formed to have a rounded shape.

In some embodiments, second contact plugs may be further formed through the insulating interlayer to contact the connecting portion. A second metal pattern having a flat top upper surface may be further formed on the second contact plugs and the insulating interlayer.

In some embodiments, the insulating interlayer may be formed by a chemical vapor deposition (CVD) process.

As described above, a generation of cracks caused by a bonding process may be decreased in the semiconductor power device. Also, the semiconductor power device may have good electric characteristics.

### BRIEF DESCRIPTION OF THE DRAWINGS

Example embodiments will be more clearly understood from the following detailed description taken in conjunction with the accompanying drawings. FIGS. 1 to 20 represent non-limiting, example embodiments as described herein.

FIG. 1 is a cross-sectional view illustrating a semiconductor power device in accordance with example embodiments;

FIGS. 2 to 10 are cross-sectional views illustrating stages of a method of manufacturing the semiconductor power device of FIG. 1;

FIG. 11 is a cross-sectional view illustrating a semiconductor power device in accordance with example embodiments;

FIG. 12A is a plan view of the semiconductor power device of FIG. 11;

FIG. 12B is a plan view of a portion of the semiconductor power of FIG. 11; and

FIGS. 13 to 20 are cross-sectional views illustrating stages of a method of manufacturing the semiconductor power device of FIG. 11.

### DESCRIPTION OF EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

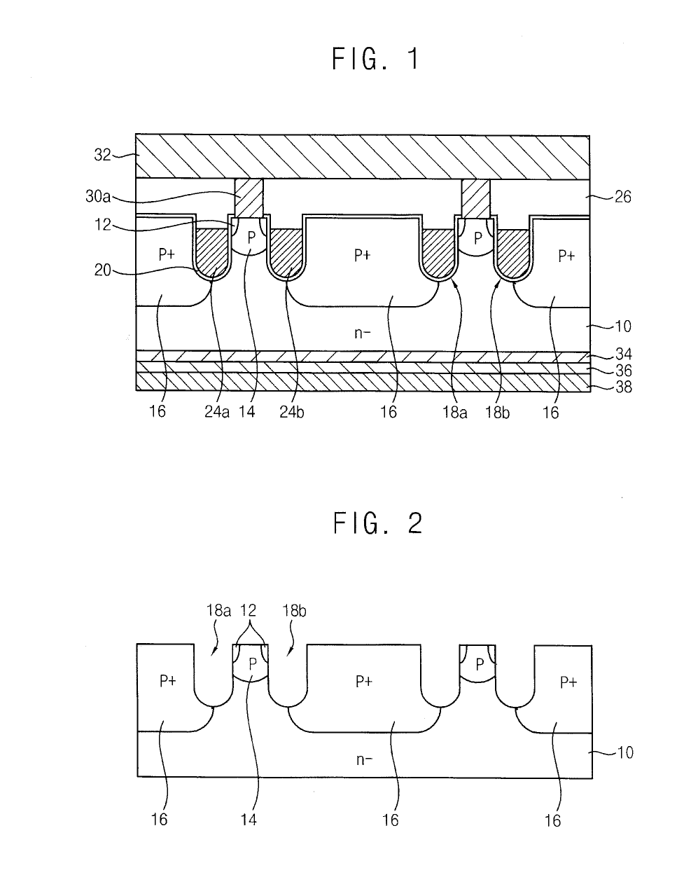

FIG. 1 is a cross-sectional view illustrating a semiconductor power device in accordance with example embodiments.

The semiconductor power device may include an insulated gate bipolar transistor (IGBT). An active region for forming cells of the semiconductor power device may be illustrated with reference to FIG. 1. A transistor of the semiconductor power device in accordance with example embodiments may serve as a power metal oxide semiconductor field effect transistor (MOSFET).

Referring to FIG. 1, the semiconductor power device may include a substrate 10, a first gate electrode 24a, a second gate electrode 24b, first and second impurity regions 12 and 14, an insulating interlayer 26, a contact plug 30a and a first metal layer 32.

The substrate 10 may include a first surface, which may be an upper surface of the substrate 10, and a second surface, which may be a lower surface opposite to the first surface. The substrate 10 may be, e.g., a silicon substrate.

The substrate 10 may be lightly doped with n-type impurities. A doping concentration of the n-type impurities in the substrate 10 may be from about 10¹³/cm³ to about 10¹⁶/cm³. In consideration of the doping concentration of the n-type impurities, the substrate 10 may be referred to as an n-minus (n−) substrate. However, the material and the doping concentration of the substrate 10 are not limited thereto.

A transistor may be formed at the first surface of the substrate 10. The transistor may be a trench gate type transistor. That is, a gate trench for forming a gate structure may be formed at an upper portion of the substrate. The gate trench may extend in a first direction. The transistor may have a channel adjacent to a sidewall of the gate trench from a bottom of the gate trench to the first surface of the substrate 10, and thus may be a vertical channel transistor.

The trench gate type transistor may include more cells per a unit area than those of a planar type transistor. Thus, the semiconductor power device including the trench gate type transistor may have a good conductivity because an integration degree of the cells and a current density in the semiconductor power device may be increased. Also, the semiconductor power device may not have a parasitic junction field effect transistor region, which may be frequently generated in a planar type transistor, and the semiconductor power device may have a high density vertical channel. Therefore, the semiconductor power device having the trench gate type transistor may have an electric characteristic better than that of a semiconductor power device having the planar type transistor. The gate structure of the trench gate type transistor may include a gate insulating layer 20 and a gate electrode structure.

The gate electrode structure may extend in the first direction. The gate electrode structure may include a pair of neighboring gate electrodes. In some embodiments, a plurality of gate electrode structures may be formed in a second direction substantially perpendicular to the first direction, and accordingly, a plurality of transistors may be formed in the second direction. That is, the gate electrode structure may include the first gate electrode 24a and the second gate electrode 24b adjacent to the first gate electrode 24a. Hereinafter, a trench for forming the first gate electrode 24a may be referred to as a first trench 18a, and a trench for forming the second gate electrode 24b may be referred to as a second trench 18b. Since the first and second gate electrodes 24a and 24b may be formed in the first and second trenches 18a and 18b, respectively, on the substrate 10, the first and second gate electrodes 24a and 24b may be buried in the substrate 10. The first and second gate electrodes 24a and 24b may include, e.g., polysilicon and/or a metal.

The gate insulating layer 20 may be conformally formed on an inner surface of the first and second gate trenches 18a and 18b. The gate insulating layer 20 may include, e.g., silicon oxide.

Upper surfaces of the first and second gate electrodes 24a and 24b may be lower than top portions of the first and second trenches, respectively. That is, the upper surfaces of the first and second gate electrodes 24a and 24b may be lower than the first surface of the substrate 10, and thus the first and second gate electrodes 24a and 24b may not protrude from the first surface of the substrate 10. Thus, the first and second gate electrodes 24a and 24b may not be connected with each other on the first surface of the substrate 10.

Because the upper surfaces of the first and second gate electrodes 24a and 24b may be lower than the top portions of the first and the second trenches 18a and 18b, respectively, damages to the first and second gate electrodes 24a and 24b caused by a polishing process may be decreased. Thus, a gate leakage current and charge trapping of the transistor including the first and second gate electrodes 24a and 24b may be decreased.

The first and second gate electrodes 24a and 24b in the gate electrode structure may be spaced apart from each other by a first gap. Hereafter, an upper portion of substrate 10 between the first and second gate electrodes 24a and 24b may be referred to as a first portion. Also, the plurality of gate electrode structures may be spaced apart from each other by a second gap. The second gap may be longer than the first gap. Hereafter, an upper portion of substrate 10 between the gate electrode structures may be referred to as a second portion.

In the first portion, the first impurity regions 12 may be disposed at upper portions of the substrate 10 adjacent to the first and second gate electrodes 24a and 24b, respectively. The first impurity regions 12 may be highly doped with n-type impurities. A doping concentration of the n-type impurities of the first impurity regions 12 may be from about 10¹⁵/cm³ of to about 10²¹/cm³. The first impurity regions 12 may have a first depth.

In the first portion, the second impurity region 14 having a second depth may be formed to surround the first impurity regions 12. The first impurity regions 12 may be disposed within the second impurity region 14. The second depth may be deeper than the first depth. Also, a bottom surface of the second impurity region 14 may be higher than bottom surfaces of the first and second gate trenches 18a and 18b.

The second impurity region 14 may be doped with impurities having a first conductivity type different from that of the first impurity regions 12. For example, the second impurity region 14 may be doped with p-type impurities. A doping concentration of the p-type impurities in the second impurity region 14 may be from about 10¹⁵/cm³ to about 10²¹/cm³. In consideration of the doping concentration of the p-type impurities, the second impurity region 14 may be referred to as a p-zero (p0) region or a p-plus (p+) region. A switching operation of the transistor may be suppressed in the second portion. That is, the transistor including the first and second gate electrodes 24a and 24b may not perform a switching operation in the second portion, and the plurality of transistors may be electrically isolated or insulated from each other. Therefore, the second gap may be longer than the first gap so as to suppress the switching operation of the transistors and to prevent a disturbance between the transistors.

A third impurity region 16 having a third depth may be formed in the second portion. The third depth may be deeper than the second depth. For example, a bottom surface of the third impurity region 16 may be lower than bottom surfaces of the first and second gate trenches 18a and 18b. The third impurity region 16 may be doped with impurities having a conductivity type the same as that of the second impurity region 14. The third impurity region 16 may have a concentration of the impurities higher than that of the second impurity region 14. That is, the third impurity region may be highly doped with p-type impurities. As the third impurity region 16 may be formed, the transistor including the first and second gate electrodes 24a and 24b may not perform a switching operation in the second portion. That is, the third impurity region 16 may serve as a floating well region.

The insulating interlayer 26 having a flat top surface may be formed on the first surface of the substrate 10 and the gate electrode structures. The insulating interlayer 26 may include, e.g., silicon oxide. The insulating interlayer 26 may be formed by a chemical vapor deposition (CVD) process.

The contact plug 30a may be formed through the insulating interlayer 26 to contact the first surface in the first portion of the substrate 10. The contact plug 30a may include a metal. For example, the contact plug 30a may include W, Au, Ag, Cu, Al, TiAlN, WN, Ir, Pt, Pd, Ru, Zr, Rh, Ni, Co, Cr, Sn, Zn, etc. The contact plug 30a may include a metal having a suitable strength to endure a chemical mechanical polishing (CMP) process. For example, the contact plug 30a may include tungsten (W). Also, the contact plug 30a may include a barrier metal layer (not shown). The insulating interlayer 26 and the contact plug 30a may have flat top surfaces. In some embodiments, a plurality of contact plugs 30a may be framed.

The first metal layer 32 having a flat top surface may be formed on the insulating interlayer 26. The first metal layer 32 may contact the contact plugs 30a. The first metal layer 32 may serve as a layer for wire bonding. Also, the first metal layer 32 may function as an emitter electrode. The first metal layer 32 may include a metal different from that of the contact plug 30a. The first metal layer 32 may include a metal having a resistance lower than that of the contact plug 30a. For example, when the contact plug 30a may include tungsten, while the first metal layer 32 may include aluminum or aluminum alloy.

Because, in accordance with principles of inventive concepts, the first metal layer 32 may have the flat top surface, the wire bonding may be easily performed, and the generation of cracks in the first metal layer 32 may be decreased.

A field stop region 34 may be formed at a lower portion of the substrate 10 adjacent to the second surface of the substrate 10. The field stop region 34 may be an n-type impurity region doped with n-type impurities. A concentration of the n-type impurities in the field stop region 34 may be from about 10¹⁴/cm³ to about 10¹⁸/cm³. In consideration of the concentration of the n-type impurities, the field stop region 34 may be referred to as an n-zero (n0) region.

A collector region 36 may be formed beneath the field stop region 34. The collector region 36 may be a p-type impurity region doped with p-type impurities.

In an example embodiment, the field stop region 34 and the collector region 36 not formed in an additional epitaxial layer on the second surface of the substrate 10, but are formed at lower potions of the substrate 10 adjacent to the second surface, and thus the semiconductor power device may be manufactured at a low cost. In another example embodiment, the field stop region 34 and the collector region 36 may be formed in an additional epitaxial layer on the second surface of the substrate 10.

A second metal layer 38 may be formed on the collector region 36. The second metal layer 38 may serve as a collector electrode.

As illustrated above, the generation of cracks in the first metal layer 32 may be decreased in exemplary embodiments in accordance with principles of inventive concepts, so that the semiconductor power device may have good characteristics.

FIGS. 2 to 10 are cross-sectional views illustrating stages of a method of manufacturing the semiconductor power device of FIG. 1 in accordance with example embodiments.

Referring to FIG. 2, a substrate 10 having a first surface and a second surface may be provided. The first surface may be an upper surface of the substrate 10 and the second surface may be a lower surface of the substrate 10 opposite to the first surface. For example, the substrate 10 may be, e.g., a silicon substrate. Also, the substrate 10 may be lightly doped with n-type impurities.

P-type impurities may be doped into a first portion of the substrate 10 to form a second impurity region 14. The second impurity region 14 may be formed to have a second depth.

N-type impurities may be highly doped into the first portion of the substrate to form a first impurity region 12. The first impurity region 12 may be formed to have a first depth shallower than the second depth. The first impurity region 12 may be formed within the second impurity region 14.

P-type impurities may be highly doped into a second portion of the substrate 10 to form a third impurity region 16. The third impurity region 16 may have a third depth deeper than the second depth. Also, the third depth may be deeper than those of first and second gate trenches 18a and 18b subsequently formed.

Sequences of forming the first to third impurity regions 12, 14 and 16 may not be limited to the above. For example, the first to third impurity regions 12, 14 and 16 may not be formed in the present step, but may be formed after forming preliminary gate electrodes 22a and 22b (refer to FIG. 4). Also, the sequences of forming the first to third impurity regions 12, 14 and 16 may be changeable.

Upper portions of the substrate 10 may be etched to form the first gate trench 18a and the second gate trench 18b. The first and second gate trenches 18a and 18b may extend in a first direction.

The first and second gate trenches 18a and 18b may be formed to be spaced apart from each other by a first gap. The first and second gate trenches 18a and 18b may define a trench structure, and a plurality of trench structures may be formed to be spaced apart from each other by a second gap. The second gap may be longer than the first gap.

The first and second impurity regions 12 and 14 may be located between the first and second trenches 18a and 18b, and the third impurity region 16 may be located between the trench structures.

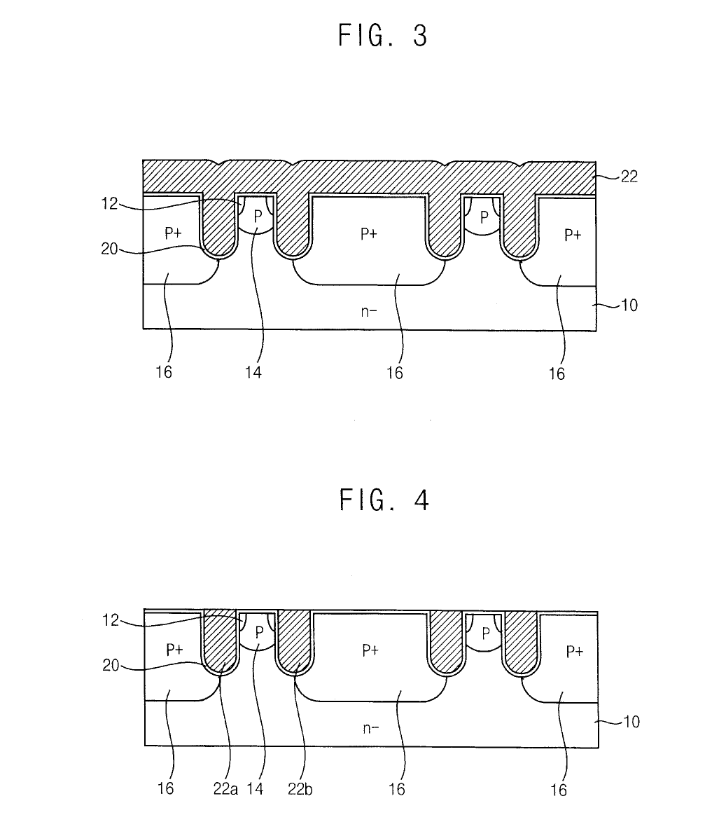

Referring to FIG. 3, a gate insulating layer 20 may be formed on inner surfaces of the first and second trenches 18a and 18b and the first surface of the substrate 10. The gate insulating layer 20 may be formed by a thermal oxidation process or a CVD process. The gate insulating layer 20 may be formed to include, e.g., silicon oxide.

A gate electrode layer 22 may be formed on the gate insulating layer 20 to fill the first and second trenches 18a and 18b. The gate electrode layer 22 may be formed to include, e.g., polysilicon and/or a metal.

Referring to FIG. 4, an upper portion of the gate electrode layer 22 may be planarized by a chemical mechanical polishing (CMP) process and/or an etch back process to form the first preliminary gate electrode 22a and the second preliminary gate electrode 22b in the first and second trenches 18a and 18b, respectively. Due to the polishing process, upper portions of the first and second preliminary gate electrodes 22a and 22b may be damaged.

Alternatively, at least one of the first to third impurity regions 12, 14 and 16 may be formed after the first and second preliminary gate electrodes 22a and 22b are formed.

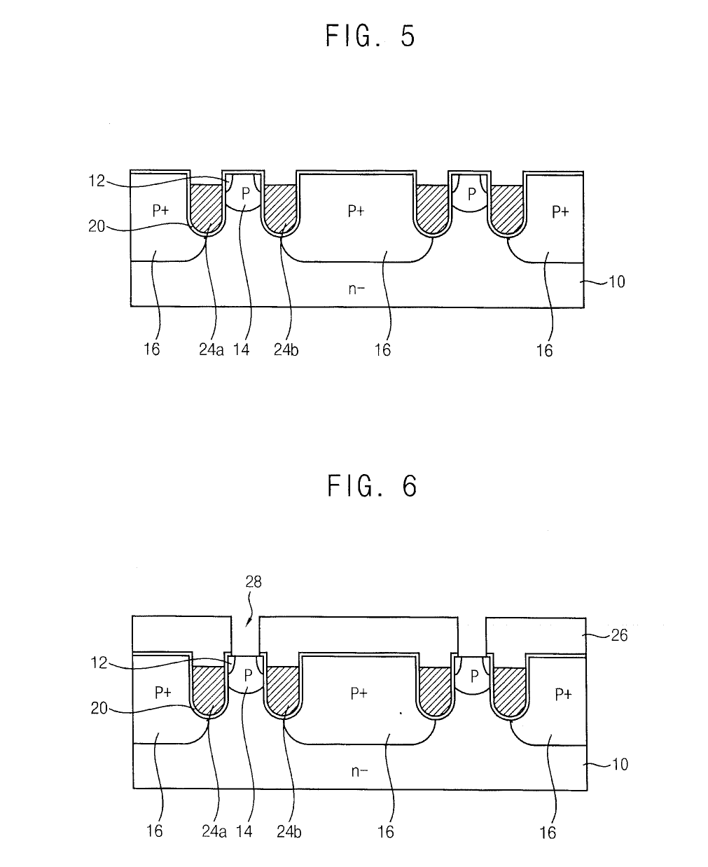

Referring to FIG. 5, upper portions of the first and second preliminary gate electrodes 22a and 22b may be partially etched to form a first gate electrode 24a and a second gate electrode 24b in the first and second trenches 18a and 18b, respectively. Upper surfaces of the first and second gate electrodes 24a and 24b may be lower than top portions of the first and second trenches 18a and 18b, respectively. Thus, the first and second gate electrodes 24a and 24b may not protrude from the first surface of the substrate 10.

The first and second gate electrodes 24a and 24b may form a gate electrode structure, and the gate insulating layer 20 and the gate electrode structure may form a gate structure.

By the etching process, the damaged upper portions of the first and second gate electrodes 24a and 24b may be removed. Thus, a gate leakage current and charge trapping of the transistor may be decreased.

Referring to FIG. 6, an insulating interlayer 26 may be formed on the substrate 10 and the gate electrode structure. The insulating interlayer 26 may be formed to include, e.g., silicon oxide. The insulating interlayer 26 may be formed by a CVD process.

Contact holes 28 may be formed by partially etching the insulating interlayer 26 to expose the first portion of the substrate 10.

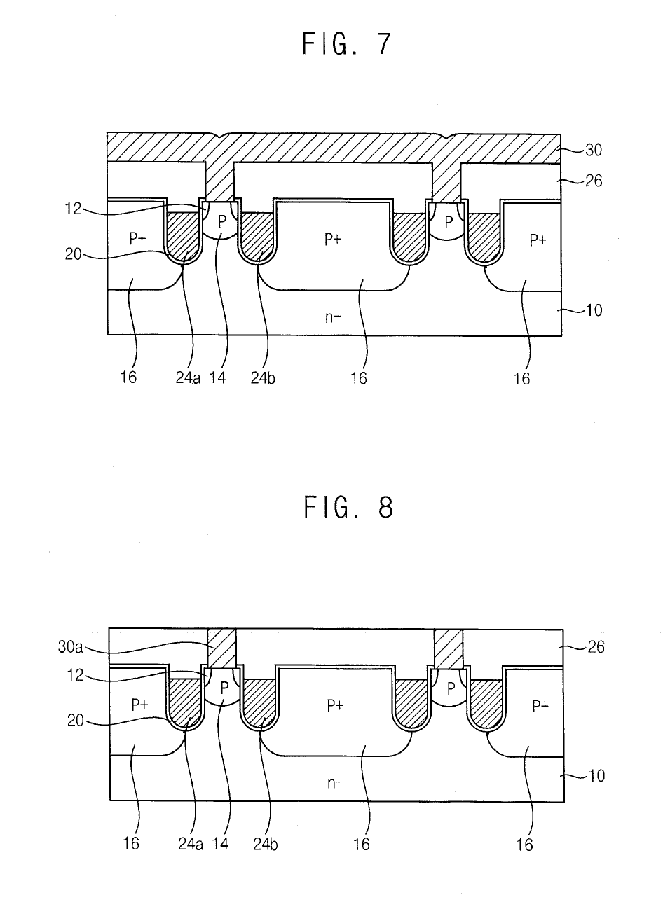

Referring to FIG. 7, a metal layer 30 may be formed on the insulating interlayer 26 to sufficiently fill the contact holes 28. In some embodiments, the metal layer 30 may be formed to include a metal having a suitable strength to endure a CMP process. In an example embodiment, a barrier metal layer (not shown) may be further formed before forming the metal layer 30 including, e.g., tungsten.

Referring to FIG. 8, an upper portion of the metal layer 30 may be planarized by a CMP process and/or an etch-back process to form contact plugs 30a in the contact holes 28, respectively.

In the planarization process, a portion of the metal layer 30 on the insulating interlayer 26 may be removed, and a top surface of the insulating interlayer 26 may be also planarized so as to be flat.

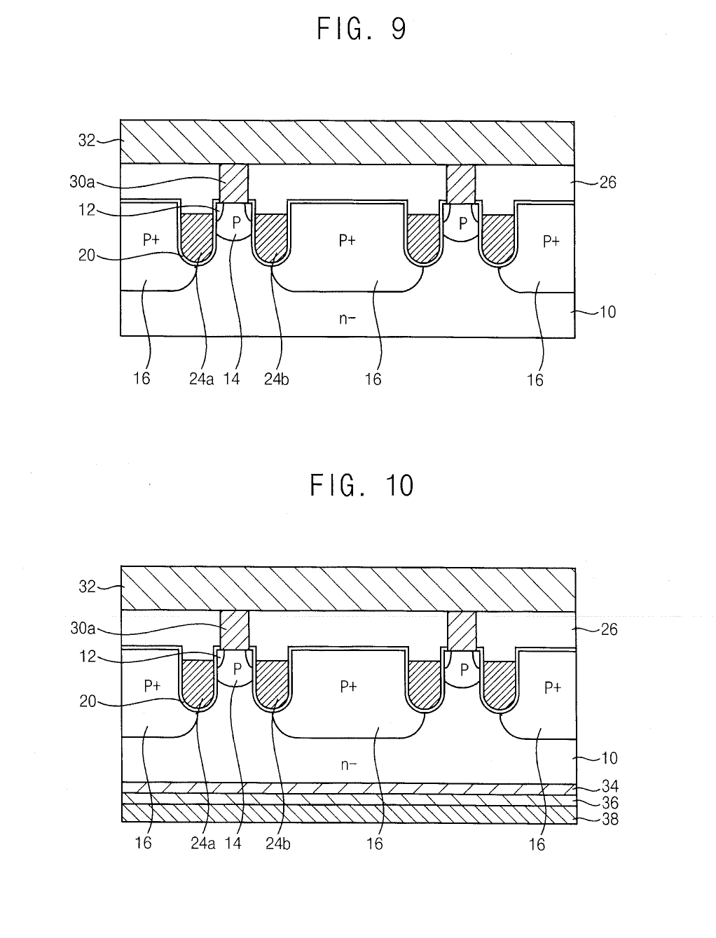

Referring to FIG. 9, a first metal layer 32 may be formed on the insulating interlayer 26 and the contact plugs 30a. Because, in accordance with principles of inventive concepts, the insulating interlayer 26 and the contact plugs 30a may have flat top surfaces, the first metal layer 32 may also have a flat top surface. The first metal layer 32 may serve as a layer for wire bonding. Also, the first metal layer 32 may serve as an emitter electrode.

The first metal layer 32 may be foil ed to have a metal having a resistance lower than that of the contact plugs 30a. For example, when the contact plugs 30a may include tungsten, the first metal layer 32 may include aluminum or aluminum alloy.

As the first metal layer 32 may have the flat top surface, any bonding damage that could caused by a wire bonding process may be decreased. As a result, in accordance with principles of inventive concepts, the generation of cracks in the first metal layer 32 having the flat top surface may be less than that of a first metal layer having an uneven top surface, such as may be found in conventional semiconductor power device. Additionally, a semiconductor power device in accordance with principles of inventive concepts may have reduced defects. Furthermore, because bonding damage may be decreased, the thickness of the first metal layer 32 may be decreased.

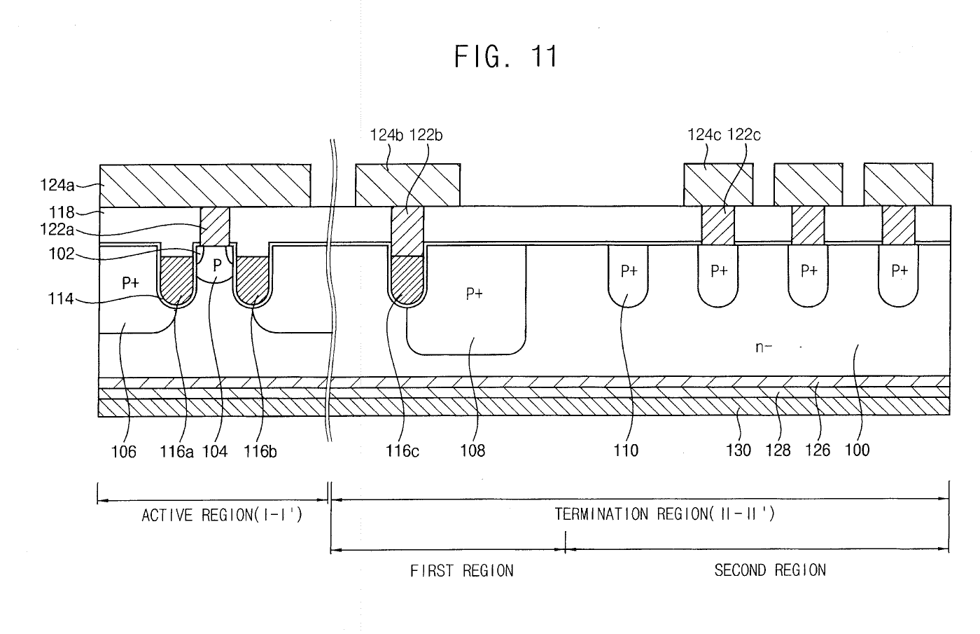

Referring to FIG. 10, a support substrate (not shown) may be formed on the metal layer 32, and the second surface of the substrate 10 may be polished so that the thickness of the substrate 10 may be reduced.

N-type impurities may be implanted onto the second surface of the substrate 10 to form a field stop region 34. A concentration of the n-type impurities implanted into the field stop region 34 may be higher than a concentration of the n-type impurities previously doped in the substrate 10.

P-type impurities may be implanted onto the second surface of the substrate 10 to form a collector region 36 beneath the field stop region 34, and thus the collector region 36 and the field stop region 34 may be sequentially disposed from the second surface of the substrate 10.

A second metal layer 38 may be formed on the second surface of the substrate 10. The second metal layer 38 may be formed on the collector region 36. The second metal layer 38 may serve as a collector electrode.

The support substrate may be removed to faun the semiconductor power device of FIG. 1.

As illustrated above, the semiconductor power device may be formed to have insulating interlayer 26 and contact plugs 30a having flat top surfaces by the planarization process. Because, in accordance with principles of inventive concepts, the first metal layer 32 may have the flat top surface, the generation of cracks in the first metal layer 32 may be decreased. Thus, the semiconductor power device may have good electric characteristics.

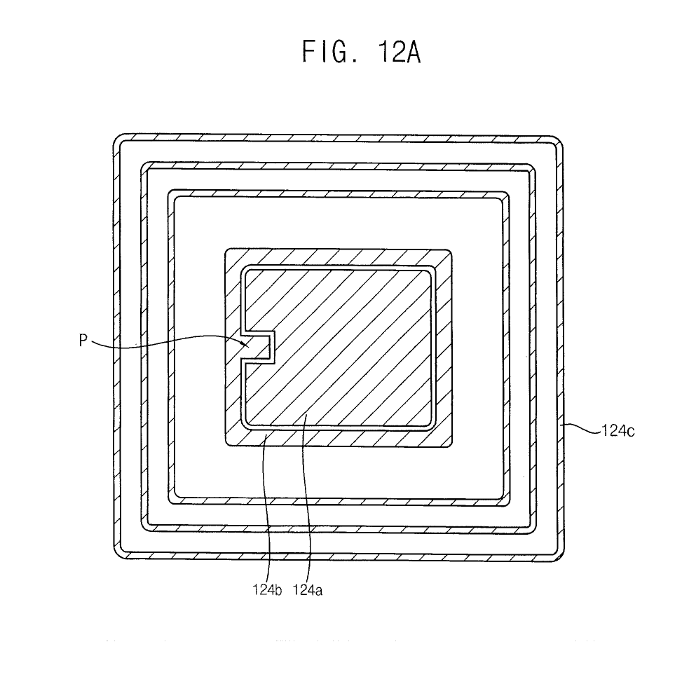

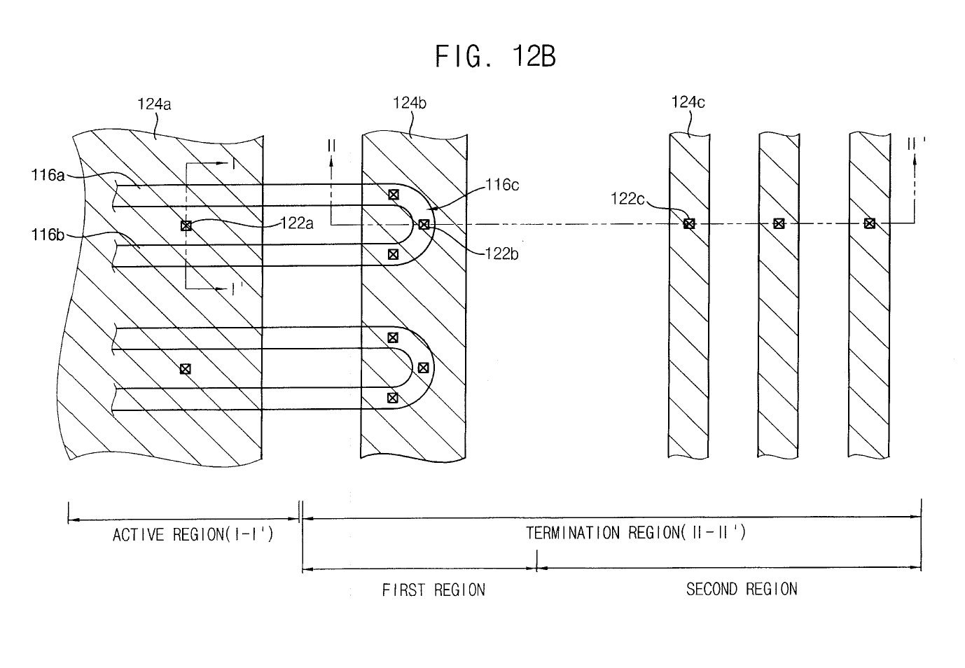

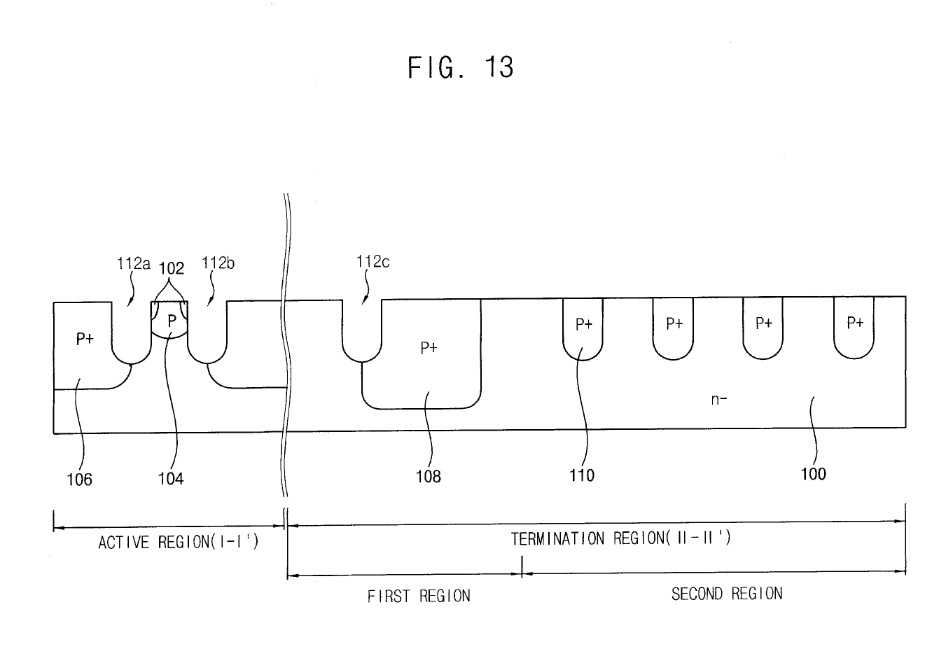

FIG. 11 is a cross-sectional view illustrating a semiconductor power device in accordance with example embodiments. FIG. 12A is a plan view of the semiconductor power device, and FIG. 12B is a plan view of an edge portion of the semiconductor power device.

The semiconductor power device may be an insulated gate bipolar transistor (IGBT), however, may not be limited thereto. Hereinafter, an active region for forming cells of the semiconductor power device and a termination region at an outside of the active region may be illustrated.

FIG. 11 shows a cross-sectional view cut along a line I-I′ and a cross-sectional view cut along a line II-II′ of FIG. 12B.

Referring to FIGS. 11, 12A and 12B, the semiconductor power device may include a substrate 100 including the active region and the termination region surrounding the active region. Hereinafter a portion of the termination region adjacent to an edge of the active region may be referred to as a first region, and a portion of the termination region surrounding the first region may be referred to as a second region.

Cells having substantially the same structure as those of FIG. 1 may be formed in the active region of the substrate 100. A trench gate type transistor may be formed in the active region and the first region of the termination region.

Each of a first gate electrode 116a and a second gate electrode 116b forming a gate electrode structure may extend in a first direction. The first and second gate electrodes 116a and 116b may extend from the active region to the first region of the termination region. End portions of the first and second gate electrodes 116a may be connected with each other by a connecting portion 116c in the first region. In a plan view, the end portions of the gate electrode structure may have a rounded shape. That is, in a plan view, the gate electrode structure may have a ring shape, and thus an electric field may not be concentrated on the connecting portion 116c.

A fourth impurity region 108 may be formed in the substrate 100 adjacent to the connecting portion 116c. The fourth impurity region 108 may be doped with impurities having a conductivity type different from that of the impurities previously doped in the substrate 100. The fourth impurity region 108 may be highly doped with p-type impurities. In a plan view, the fourth impurity region 108 may have a ring shape surrounding the active region.

The fourth impurity region 108 may serve as a junction termination extension (JTE) region for preventing an electric field from being concentrated at the edge portion of the semiconductor power device. A depth of the fourth impurity region 108 may be deeper than depths of the impurity regions in the active region, so that the electric field may be effectively prevented from being concentrated at the edge portion. Due to the fourth impurity region 108, the semiconductor power device may have a high breakdown voltage.

A fifth impurity region 110 may be formed to be spaced apart from the fourth impurity region 108. The fifth impurity region 110 may serve a junction termination ring for preventing an electric field from being concentrated at the edge portion of the semiconductor power device. In some embodiments, a plurality of fifth impurity regions 110 may be disposed to have a concentric circular ring shape surrounding the active region. The fifth impurity region 110 may be doped with impurities having a conductivity type different from that of the impurities previously doped in the substrate 100. The fifth impurity region 110 may be highly doped with p-type impurities. The fifth impurity region 110 may have an electrically floating state. Due to the fifth impurity region 110, the concentration of an electric field at the edge portion of the semiconductor power device may be decreased.

An insulating interlayer 118 may be formed on the active region and the termination region of the substrate 100. The insulating interlayer 118 may have a flat top surface. The insulating interlayer 118 may include, e.g., silicon oxide. The insulating interlayer 118 may be formed by a chemical vapor deposition (CVD) process.

A first contact plug 122a may be formed through the insulating interlayer 118 in the active region to contact the first surface in the first portion of the substrate 100. A second contact plug 122b may be formed through the insulating interlayer 118 in the first region to contact the connecting portion 116c between the first and second gate electrodes 116a and 116b. In some embodiments, a plurality of first contact plugs 122a and a plurality of second contact plugs 112b may be formed. Also, at least one third contact plug 122c may be formed through the insulating interlayer 118 in the second region to contact at least one of the fifth impurity regions 110.

The first to third contact plugs 122a, 122b and 122c may include substantially the same metal. For example, the first to third contact plugs 122a, 122b and 122c may include W, Au, Ag, Cu, Al, TiAlN, WN, Ir, Pt, Pd, Ru, Zr, Rh, Ni, Co, Cr, Sn, Zn, etc.

In some embodiments, the first to third contact plugs 122a, 122b and 122c may include a metal having a suitable strength to endure a chemical mechanical polishing (CMP) process. Each of the first to third contact plugs 122a, 122b and 122c may include a barrier metal layer (not shown) and a metal layer (not shown) including, e.g., tungsten. The insulating interlayer 118 and the first to third contact plugs 122a, 122b and 122c may have flat top surfaces.

A first metal layer pattern 124a having a flat top surface may be formed on the insulating interlayer 118 in the active region. The first metal layer pattern 124a may contact the first contact plug 122a.

The first metal layer pattern 124a may cover most of the active region. The first metal layer pattern 124a may serve as a layer for wire bonding. Also, the first metal layer pattern 124a may serve as an emitter electrode. As the first metal layer pattern 124a may have the flat top surface, the wire bonding may be easily performed, and a generation of cracks in the first metal layer pattern 124a may be decreased.

A second metal layer pattern 124b may be formed on the insulating interlayer 118 to contact the second contact plug 122b in the first region. The first and second gate electrodes 116a and 116b of the gate structure in the active region may be electrically connected to each other by the second metal layer pattern 124b. That is, the second metal layer pattern 124b may serve as a signal bus line that may be electrically connected to the gate electrode structures in the active region, and may contact a pad electrode P for receiving an external signal. The second metal layer pattern 124b may have a ring shape surrounding the active region. As the second metal layer pattern 124b may include a metal having a low resistance, the semiconductor power device may have good electric characteristics. In addition, the second metal layer pattern 124b may serve as a field plate pattern for preventing an electric field from being concentrated at the edge portion of the semiconductor power device.

A third metal layer pattern 124c may be formed on the insulating interlayer 118 to contact the third contact plug 122c, in the second region. In some embodiments, a plurality of third metal layer patterns 124c may be formed to contact the third contact plugs 122c, respectively. Due to the third metal layer pattern 124c electrically connected to the termination ring, the concentration of the electric field may be decreased.

The first, second and third metal layer patterns 124a, 124b and 124c may include substantially the same metal. The first, second and third metal layer patterns 124a, 124b and 124c may have flat top surfaces. The first, second and third metal layer patterns 124a, 124b and 124c may include a metal different from that of the first, second and third contact plugs 122a, 122b and 122c. The first, second and third metal layer patterns 124a, 124b and 124c may include a metal having a resistance lower than that of the first, second and third contact plugs 122a, 122b and 122c. For example, when the first, second and third contact plugs 122a, 122b and 122c may include tungsten, the first, second and third metal layer patterns 124a, 124b and 124c may include aluminum or aluminum alloy.

A field stop region 126 and a collector region 128 may be formed at lower portions of the substrate 100 adjacent to the second surface of the substrate 100. Also, a second metal layer 103 may be formed on the second surface of the substrate 100. The second metal layer 130 may be formed on the collector region 128. The field stop region 126, the collector region 128 and the second metal layer 130 may be formed, as illustrated in FIG. 1.

FIGS. 13 to 20 are cross-sectional views illustrating stages of a method of manufacturing the semiconductor power device of FIG. 11 in accordance with example embodiments.

Referring to FIG. 13, a substrate 100 having a first surface and a second surface opposite to the first surface may be provided. An active region and a termination region surrounding the active region may be defined in the substrate 100. The substrate 100 may be, e.g., a silicon substrate. The substrate 100 may be lightly doped with n-type impurities.

A first impurity region 102, a second impurity region 104 and a third impurity region 106 may be formed in the active region of the substrate 100 as follows.

P-type impurities may be doped into a first portion of the substrate 100 to form the second impurity region 104. The second impurity region 104 may be formed to have a second depth. P-type impurities may be highly doped into the first portion of the substrate 100 to form the first impurity region 102. The first impurity region 102 may have a first depth shallower than the second depth. The first impurity region 102 may be formed in the second impurity region 104. Also, p-type impurities may be doped into a second portion of the substrate 100 to form the third impurity region 106. The third impurity region 106 may be foamed to have a third depth deeper than the second depth. The third impurity region 106 may serve as a floating well region.

A fourth impurity region 108 and a fifth impurity region 110 may be formed in the termination region of the substrate 100 as follows.

P-type impurities may be highly doped into the substrate 100 of the first region adjacent to the connecting portion 116c between the first and second gate electrodes 116a and 116b to form the fourth impurity region 108. The fourth impurity region 108 may serve as a JTE region. In a plan view, the fourth impurity region 108 may have a ring shape surrounding the active region. The fourth impurity region 108 may have a depth deeper than that of the impurity regions in the active region. P-type impurities may be highly doped into second region of the substrate 100 to form the fifth impurity region 110. In a plan view, the fifth impurity region 110 may be formed to have a concentric circular ring shape surrounding the active region. The fifth impurity region 110 may serve as a termination ring.

Upper portions of the substrate 100 in the active region and the first region may be etched to form a first trench 112a, a second trench 112b and third trench 112c. The third trench 112c may be formed between the first and second trenches 112a and 112b in the first region so that the first to third trenches 112a, 112b and 112c may be in fluid communication with each other. In a plan view, the third trench 112c may have a rounded shape.

The first and second gate trenches 112a and 112b may be formed to be spaced apart from each other by a first gap. The first to third trenches 112a, 112b and 112c may have a ring shape. The first to third trenches 112a, 112b and 112c define a trench structure, and a plurality of trench structures may be formed to be spaced apart from each other by a second gap. The second gap may be longer than the first gap.

The first and second impurity regions 102 and 104 may be formed between the first and second trenches 112a and 112b, and the third impurity region 106 may be formed between the trench structures.

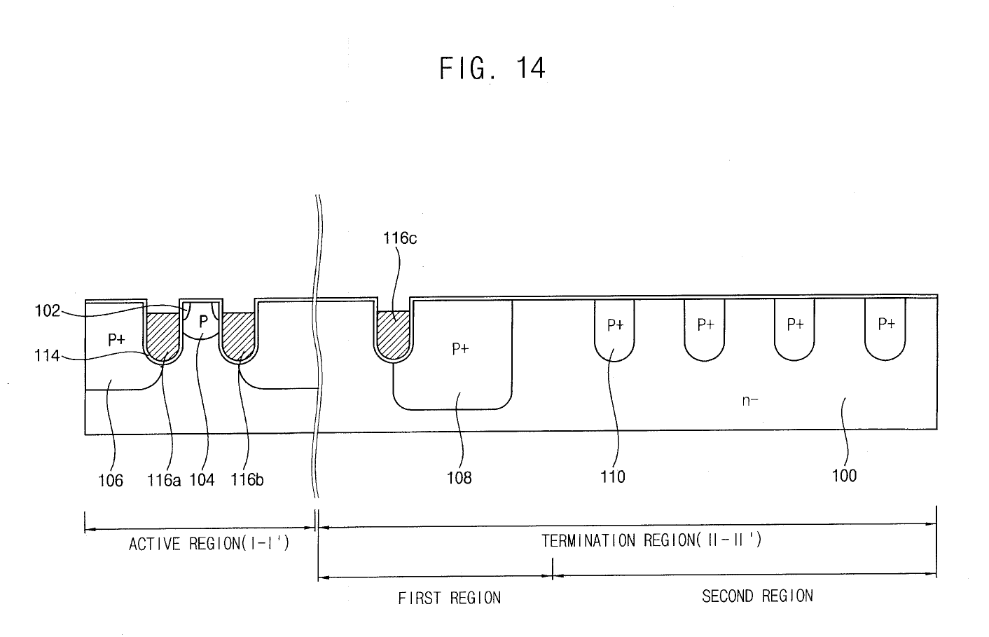

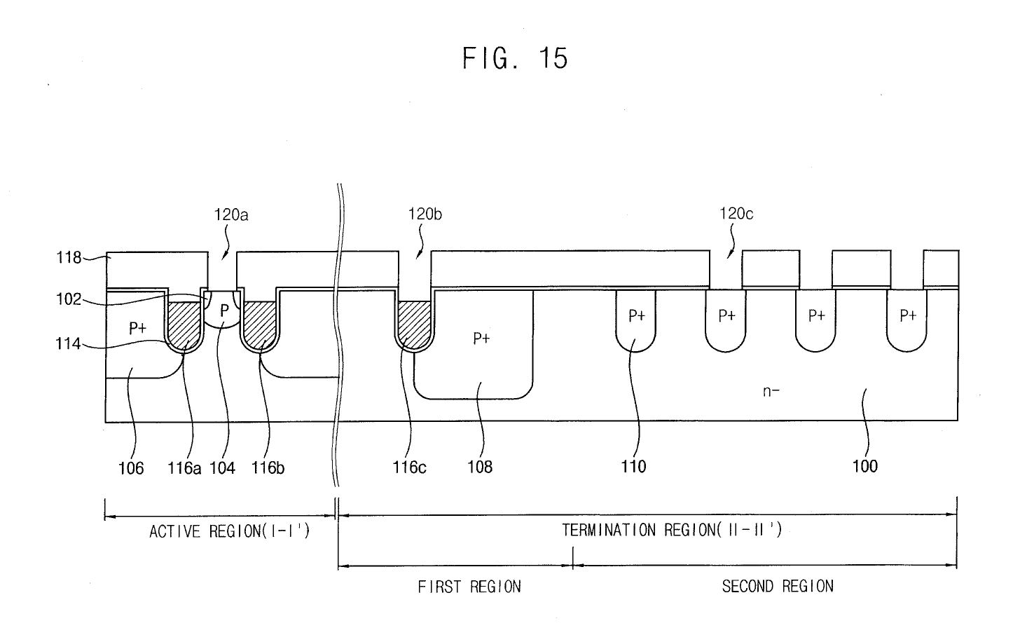

Referring to FIG. 14, a gate insulating layer 114 may be formed on inner surfaces of the first to third trenches 112a, 112b and 112c and the first surface of the substrate 100.

Particularly, a gate electrode layer may be formed on the gate insulating layer 114 to fill the first to third trenches 112a, 112b and 112c. The gate electrode layer may be formed to include, e.g., polysilicon and/or a metal. An upper portion of the gate electrode layer may be planarized by a chemical mechanical polishing (CMP) process and/or an etch back process to form a preliminary gate electrode in the first to third trenches 112a, 112b and 112c. Upper portions of the preliminary gate electrode may be etched to form a gate electrode structure including a first gate electrode 116a, a second gate electrode 116b and a connecting portion 116c in the first to third trenches 112a, 112b and 112c, respectively. The gate electrode structure may be formed by performing substantially the same processes as those illustrated with reference to FIGS. 4 and 5.

Referring to FIG. 15, an insulating interlayer 118 may be formed on the gate electrode structure and the substrate 100. The insulating interlayer 118 may be formed to include, e.g., silicon oxide. The insulating interlayer 118 may be formed by a CVD process.

A first contact hole 120a may be formed by partially etching the insulating interlayer 118 to expose the first portion of the substrate 100. In the etching process, a second contact hole 120b may be formed to expose a top surface of the connecting portion 116c, in the first region, and at least one third contact hole 120c may be formed to expose a top surface of at least one of the fifth impurity region 110.

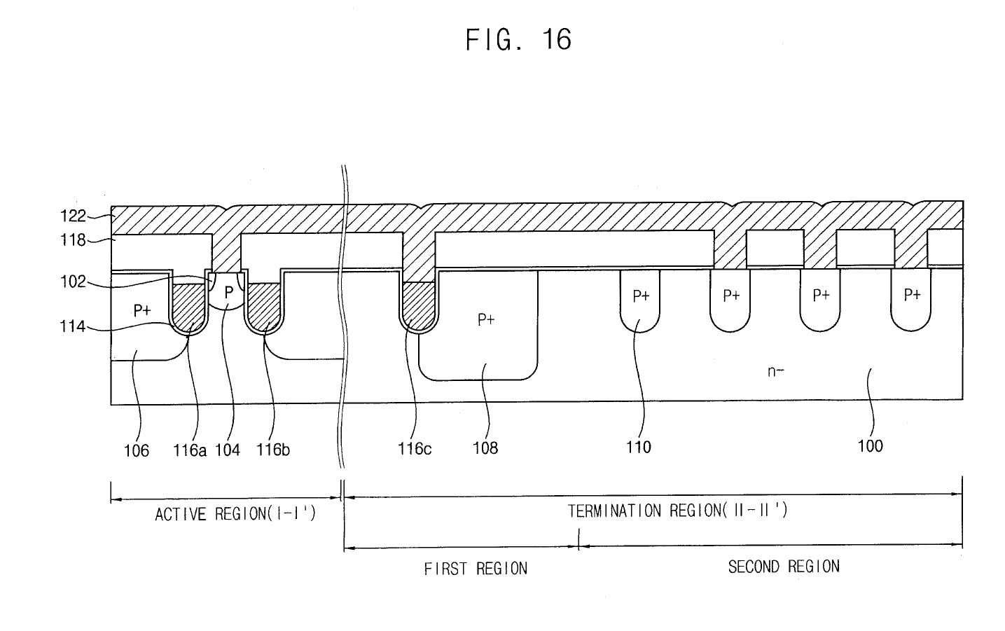

Referring to FIG. 16, a metal layer 122 may be formed on the insulating interlayer 118 to sufficiently fill the first to third contact holes 120a, 120b and 120c. In some embodiments, the metal layer 122 may be formed to include a metal having a suitable strength to endure a CMP process. In an example embodiment, a barrier metal layer (not shown) may be further formed before forming the metal layer 122 including, e.g., tungsten.

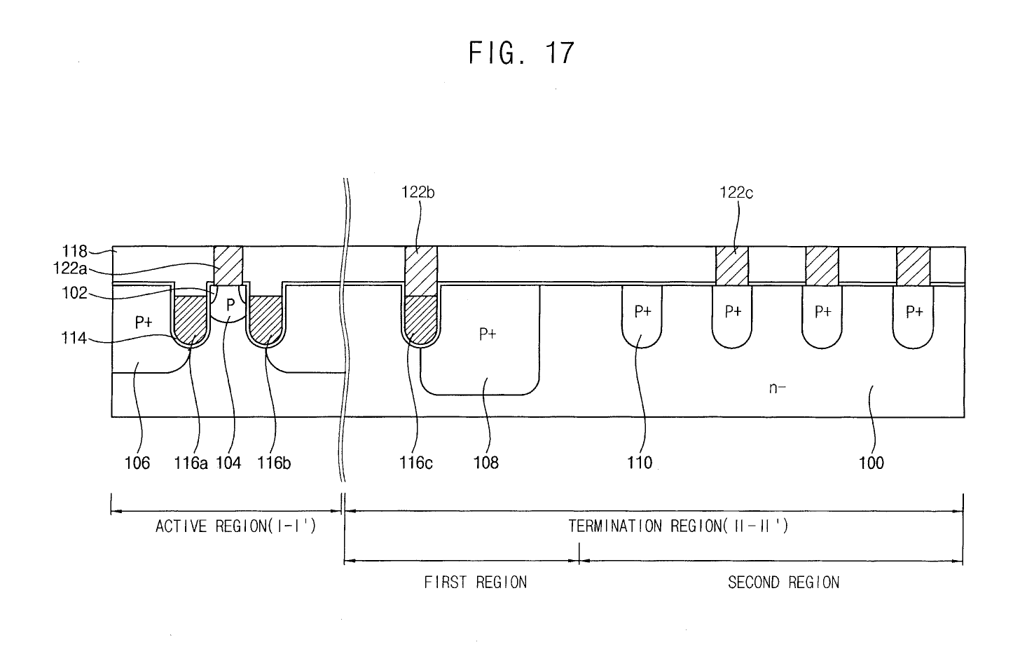

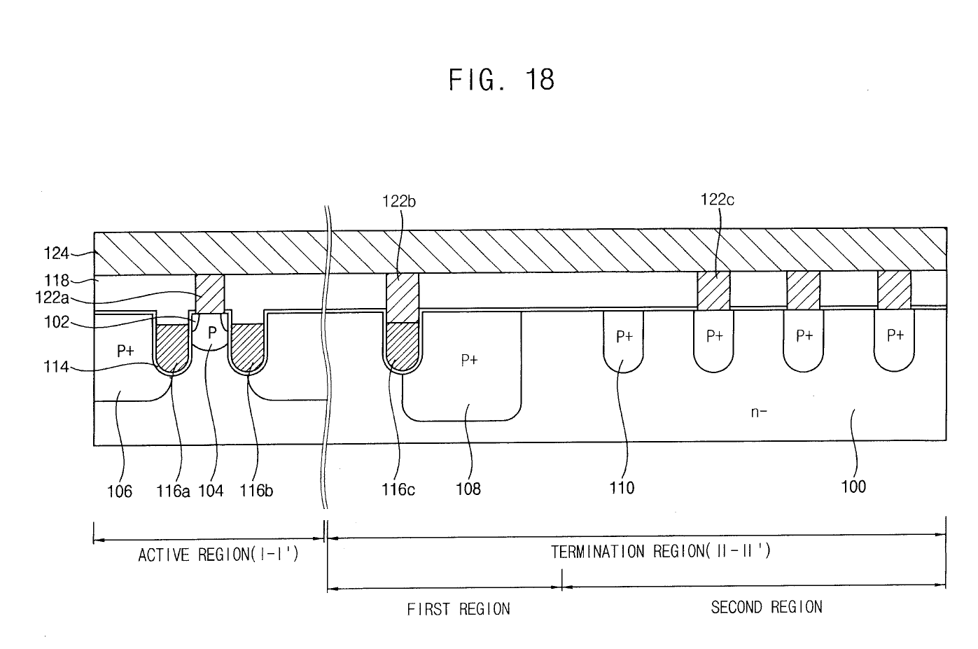

Referring to FIG. 17, an upper portion of the metal layer 122 may be planarized by a CMP process and/or an etch back process to form the first to third contact plugs 122a, 122b and 122c in the first to third contact holes 120a, 120b and 120c, respectively. In the planarization process, a top surface of the insulating interlayer 118 may be also planarized so as to be flat.

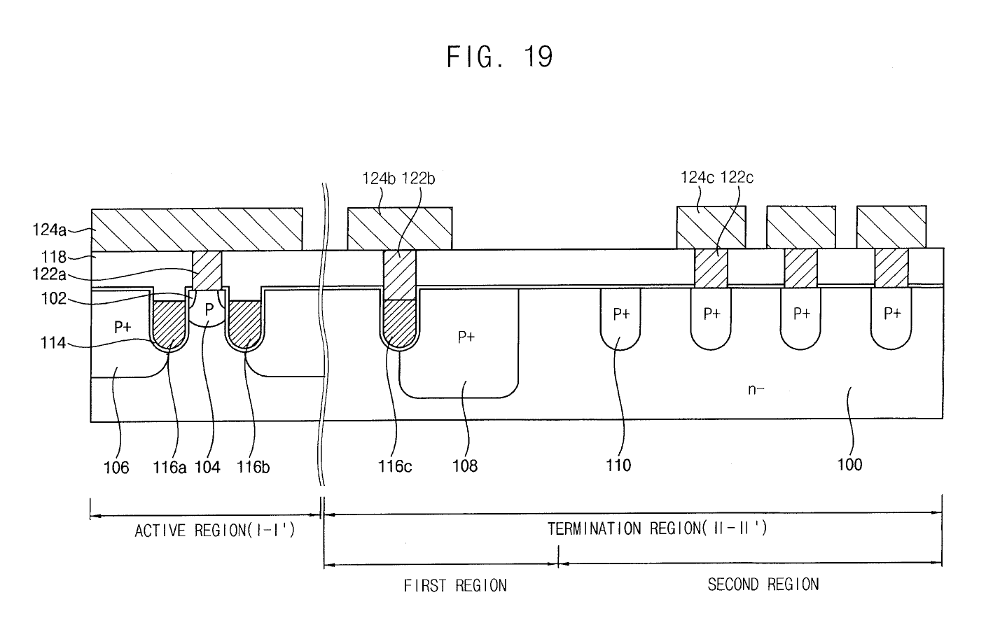

Referring to FIG. 18, a first metal layer 124 may be formed on the insulating interlayer 118 and the first to third contact plugs 122a, 122b and 122c. As the insulating interlayer 118 and the first to third contact plugs 122a, 122b and 122c may have flat top surfaces, the first metal layer 124 may also have a flat top surface. The first metal layer 124 may be formed to have a metal different from that of the first to third contact plugs 122a, 122b and 122c. The first metal layer 124 may be formed to have the metal having a resistance lower than that of the first to third contact plugs 122a, 122b and 122c. For example, when the first to third contact plugs 122a, 122b and 122c may include tungsten, the first metal layer 124 may include aluminum or aluminum alloy.

Referring to FIG. 19, a first metal layer pattern 124a, a second metal layer pattern 124b and a third metal layer pattern 124c may be formed by patterning the first metal layer 124.

The first metal layer pattern 124a may be formed on the insulating interlayer 118 in the first region. The first metal layer pattern 124a may serve as an emitter electrode.

The second metal layer pattern 124b may be formed on the insulating interlayer 118 in the first region to contact the second contact plug 122b. The second metal layer pattern 124b may be electrically connected to the gate electrode structures in the active region. Thus, the second metal layer pattern 124b may serve as a gate bus line. The second metal layer pattern 124b may have a ring shape surrounding the active region. Also, the second metal layer pattern 124b may serve as a gate field plate pattern.

The third metal layer pattern 124c may be formed on the insulating interlayer 118 in the second region to contact the third contact plug 122c. Due to the third metal layer pattern 124c, the concentration of an electric field at the edge portion of the active region may be decreased.

As the first metal layer 124 may have the flat top surface, the first to third metal layer patterns 124a, 124b and 124c may have flat top surfaces, and thus a generation of cracks in the first to third metal layer patterns 124a, 124b and 124c may be decreased. As the second metal layer 124b may include the metal having a low resistance, the gate electrode structures in the active region may be electrically connected to each other to have a low resistance.

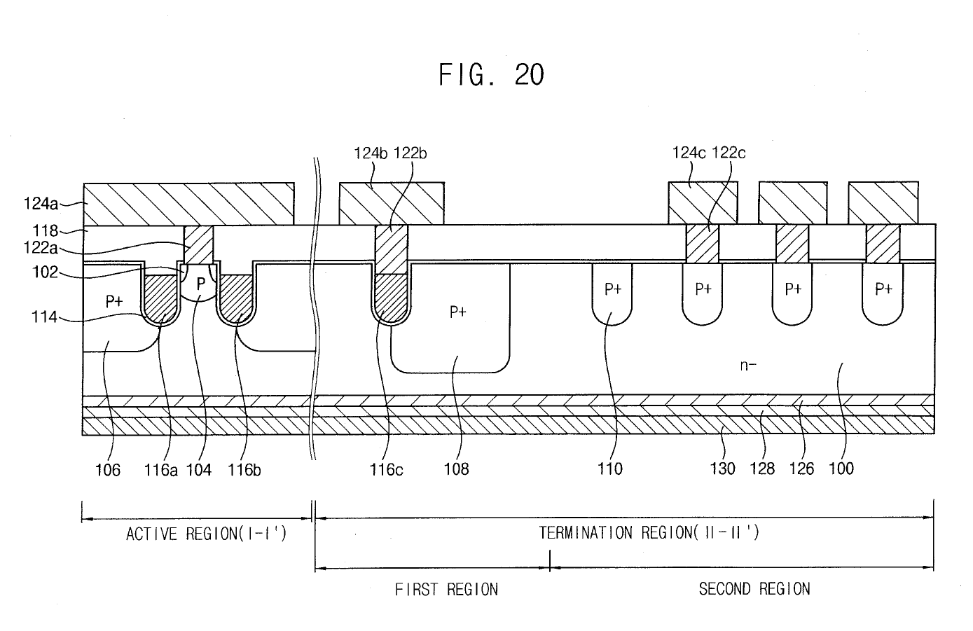

Referring to FIG. 20, a support substrate (not shown) may be formed on the first surface of the substrate 100, and the second surface of the substrate 100 may be polished so that a thickness of the substrate 100 may be reduced.

A field stop region 126 and a collector region 128 may be formed at lower portions of the substrate 100 adjacent to the second surface of the substrate 100. Also, a second metal layer 130 may be formed on the second surface of the substrate 100. The second metal layer 130 may be formed on the collector region 128. The support substrate may be removed.

The field stop region 126, the collector region 128 and the second metal layer 130 may be formed on the second surface of the substrate 100, as illustrated in FIG. 9.

As illustrated above, in accordance with principles of inventive concepts, the generation of defects may be decreased, so that a semiconductor power device may have good characteristics.

What is claimed is:

1. A semiconductor power device, comprising:
a substrate including an active region and a termination region;
a first gate electrode and a second gate electrode buried in the substrate, wherein upper surfaces of the first and second gate electrodes are lower than an upper surface of the substrate therebetween;
a first impurity region in the substrate between the first and second electrodes;
an insulating interlayer having a flat top surface on the substrate, the insulating interlayer covering the upper surfaces of the first and second gate electrodes;
a first contact plug passing through the insulating interlayer to contact the first impurity region; and
a first metal layer pattern having a flat top surface on the first contact plug and the insulating interlayer.

2. The semiconductor power device of claim 1, further comprising:
a third gate electrode buried in the substrate, the third gate electrode being spaced apart from the second gate electrode; and
a floating well region between the second gate electrode and the third gate electrode.

3. The semiconductor power device of claim 2, wherein the bottommost level of the floating well region is lower than the bottommost level of the second and third gate electrodes.

4. The semiconductor power device of claim 2, wherein the substrate is doped with an n-type impurity.

5. The semiconductor power device of claim 4, wherein the floating well region is doped with a p-type impurity.

6. The semiconductor power device of claim 1, wherein the bottommost level of the first impurity region is higher than the bottommost level of the first and second gate electrode.

7. The semiconductor power device of claim 1, further comprises a gate insulating layer between the first, second, and third gate electrodes and the substrate.

8. The semiconductor power device of claim 1, wherein the first and second gate electrodes extend from the active region to the termination region, the first and second gate electrodes having a connecting portion for connecting the first and second gate electrodes to each other in the termination region.

9. The semiconductor power device of claim 1, wherein the connecting portion has a rounded shape.

10. The semiconductor power device of claim 8, further comprising:
a second contact plug passing through the insulating interlayer to contact with the connecting portion; and
a second metal layer pattern on the second contact plug and the insulating interlayer, the second metal layer pattern having a flat top surface.

11. The semiconductor power device of claim 10, wherein the second metal layer pattern is electrically connected to the first and second gate electrodes in the active region.

12. The semiconductor power device of claim 10, wherein the second metal layer pattern surrounds the active region.

13. The semiconductor power device of claim 10, wherein the first and second contact plugs include a metal.

14. The semiconductor power device of claim 1, further comprising:
a second impurity region for preventing from a concentration of an electric field in the termination region of the substrate, the second impurity region being spaced apart from the first and second gate electrodes and surrounding the active region.

15. The semiconductor power device of claim 14, further comprising a field stop region, a collector region and a third metal layer pattern at a lower portion of the substrate, the field stop region being between the floating well and the collector region.

16. The semiconductor power device of claim 15, wherein the collector region is between the field stop region and the third metal layer pattern.

17. A semiconductor power device, comprising:
a first trench and a second trench in a substrate;
a first gate electrode in the first trench and a second gate electrode in the second trench, wherein upper surfaces of the first and second gate electrodes are lower than an upper surface of the substrate therebetween;
a first impurity region in the substrate between the first and second electrodes;
an insulating interlayer having a flat top surface on the substrate, the insulating interlayer covering the upper surfaces of the first and second gate electrodes;
a first contact plug passing through the insulating interlayer to contact the first impurity region;
a first metal layer pattern having a flat top surface on the first contact plug and the insulating interlayer;
a collector region disposed at a lower portion of the substrate; and
a second metal layer pattern under the collector region.

18. The semiconductor power device of claim 17, further comprising:
a third trench in the substrate, the third trench being spaced apart from the second trench;
a third gate electrode in the third trench; and
a floating well region between the second trench and the third trench.

19. The semiconductor power device of claim 18, wherein the bottommost of the floating well region has a level lower than the bottommost level of the second and third trenches.

20. A semiconductor power device, comprising:
a substrate including an active region and a termination region;
a first trench and a second trench in the substrate;
a first gate electrode in the first trench and a second gate electrode in the second trench, wherein upper surfaces of the first and second gate electrodes are lower than an upper surface of the substrate therebetween;
a first impurity region in the substrate between the first and second electrodes;
an insulating interlayer having a flat top surface on the substrate, the insulating interlayer covering the upper surfaces of the first and second gate electrodes;
a first contact plug passing through the insulating interlayer to contact the first impurity region;
a first metal layer pattern having a flat top surface on the first contact plug and the insulating interlayer;
a collector region disposed at a lower portion of the substrate; and
a second metal layer pattern under the collector region,
wherein the first and second gate electrodes extend from the active region to the termination region, the first and second gate electrodes having a connecting portion for connecting the first and second gate electrodes to each other in the termination region.
